(19) United States
(12) Patent Application Publication
(10) Pub. No.: US 2009/0226162 A1
(43) Pub. Date: Sep. 10, 2009

(54) Auto-prioritizing service impacted optical fibers in massive collapsed rings network outages

(76) Inventors: Jami Cheng, Dublin, OH (US); Paritosh Bajpay, Edison, NJ (US); Stephen J. Griesmer, Westfield, NJ (US); Eshrat J. Huda, Hillsborough, NJ (US); David H. Lu, Morganville, NJ (US)

Correspondence Address: AT & T LEGAL DEPARTMENT - Canavan, ATTN: PATENT DOCKETING, ROOM 2A-207, ONE AT & T WAY, BEDMINSTER, NJ, 07921, US

(21) Appl. No.: 12/075,041

(22) Filed: Mar. 7, 2008

(51) Int. Cl. G01R 31/08

(52) U.S. Cl. 398/3

(57) ABSTRACT

A method is disclosed that by correlating the network fault management, circuit provisioning data and cable inventory data, it can identify the most critical network elements that can be fixed in order to restore the services quickly in a network outage that involves high number of collapsed rings. This method can also be used for proactive network maintenance, to avoid chokepoints when provisioning circuits for mission critical facilities.

### BACKGROUND OF THE INVENTION

The invention relates generally to improving network maintenance efficiency and speeding-up failure recovery. More specifically, the invention is a method for identifying the critical network elements that can be fixed in order to quickly restore services after a massive telecommunication outage. The method auto-prioritizes the order of repair after a network outage caused by a high number of collapsed rings or can be used by network engineering to avoid chokepoints when provisioning circuits for mission critical facilities.

Telecommunications providers construct, operate, and maintain utilities above and below ground. These utilities are an asset as well as a responsibility. The most common hazard to communications integrity is accidental severing caused by excavation or by accident. A mistake can damage or sever an optical fiber disrupting communication services on a grand scale.

For network fibers in metropolitan areas, their high density and geographical constraints have reduced available network diversity. This has resulted in many network chokepoints due to shared cables, access point, conduits and enclosures among network rings.

A ring network is a network topology in which each node connects to exactly two other nodes, forming a circular pathway for signals. Data travels from node to node, with each node handling every packet. Because a ring topology provides only one pathway between any two nodes, ring networks may be disrupted by the failure of a single link. A node failure or cable break might isolate every node attached to the ring.

There have been incidents where a single chokepoint has caused many rings to collapse, resulting in lost service of mission critical facilities, high customer impacts and extended time to repair. A chokepoint in network may be the cable that is shared by multiple rings, a conduit that is shared with fibers in primary and back-up rings, or a shared access point, for example a manhole to access the fiber termination points. FIG. 1 shows a simplified representation of a network incident that occurred in Philadelphia, Pa., and lasted approximately 81 hours due to a fire in a service manhole which resulted in the failure of multiple metropolitan fiber facilities belonging to an IntereXchange Carrier (IXC). More than 90 rings were involved and 13 resulted in collapsed rings. FIG. 2 shows a simplified representation of a network ingress/egress proximity violation.

### SUMMARY OF THE INVENTION

The inventors have discovered that it would be desirable to have a method that identifies critical network elements automatically and allows a network support center to prioritize the order of repair after a massive network outage has occurred due to physical communication elements damage. The method improves network recovery and reduces damage to a minimum.

One aspect of the invention provides a method for prioritizing the order of repair of network element damage after a network outage caused by a high number of collapsed rings. Methods according to this aspect include receiving ring identifiers for the collapsed rings and their geographical market zone from a network fault management system, importing ring-to-fiber correlation data from a circuit provisioning database based on the collapsed ring and geographical market zone identifiers, importing geographical cable layouts, associated conduits, enclosures, optical fiber termination points, access points, and other physical data from a cable inventory database based on the collapsed ring and geographical market zone identifiers, performing a proximity check on the correlation data, performing a diversity check on the correlation data, flagging shared network elements identified by the proximity and diversity checks, calculating a severity for each shared network element, and prioritizing the shared network elements' severities.

Another aspect of the invention provides a method for prioritizing the criticality of network elements in rings when provisioning circuits. Methods according to this aspect include receiving identifiers for the rings and their geographic market zone, importing ring-to-fiber correlation data from a circuit provisioning database based on the ring and geographical market zone identifiers, importing geographical cable layouts, associated conduits, enclosures, optical fiber termination points, access points, and other physical data from a cable inventory database based on the ring and geographical market zone identifiers, performing a proximity check on the correlation data, performing a diversity check on the correlation data, flagging shared network elements identified by the proximity and diversity checks, calculating a severity for each shared network element, and prioritizing the shared network elements' severities.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

FIG. 1 is an exemplary transport layer network ring architecture showing how a multiple ring could collapse due to a single point of failure.

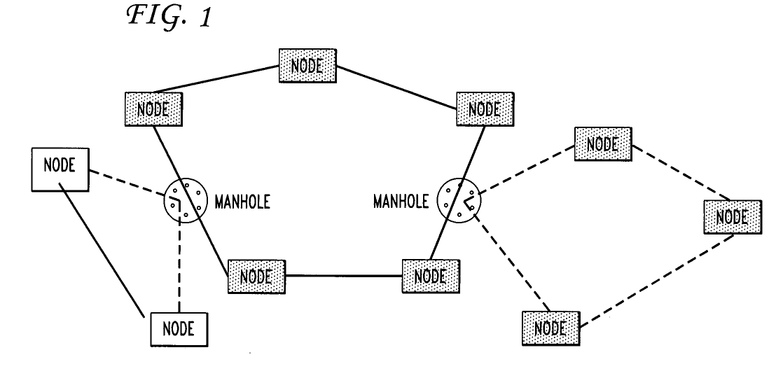

FIG. 2 is an exemplary fiber layout showing an ingress/egress proximity violation for cables to a building.

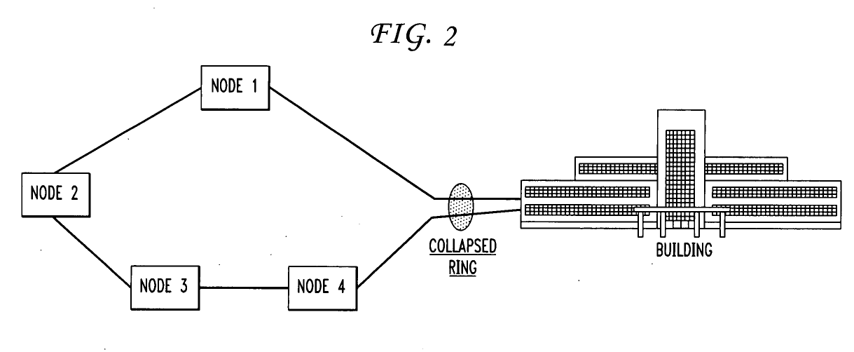

FIG. 3 is an exemplary method for auto-prioritizing network chokepoints.

### DETAILED DESCRIPTION

Embodiments of the invention will be described with reference to the accompanying drawing figures wherein like numbers represent like elements throughout. Before embodiments of the invention are explained in detail, it is to be understood that the invention is not limited in its application to the details of the examples set forth in the following description or illustrated in the figures. The invention is capable of other embodiments and of being practiced or carried out in a variety of applications and in various ways. Also, it is to be understood that the phraseology and terminology used herein is for the purpose of description and should not be regarded as limiting. The use of “including,” “comprising,” or “having,” and variations thereof herein is meant to encompass the items listed thereafter and equivalents thereof as well as additional items.

The invention is not limited to any particular software language described or implied in the figures. A variety of alternative software languages may be used for implementation of the invention. The invention is not limited to any network fault management system, circuit provisioning database or cable inventory database. The correlation method may be applied to any existing conventional network fault management system, circuit provisioning database or cable inventory database. Some components and items are illustrated and described as if they were hardware elements, as is common practice within the art. However, various components in the method and apparatus may be implemented in software or hardware such as C++, XML and processors.

Embodiments of the invention provide methods, and computer-usable media storing computer-readable instructions for execution on a computer for auto-prioritizing network chokepoints. The invention is a modular framework and is deployed as software as an application program tangibly embodied on a program storage device. The application code for execution can reside on a plurality of different types of computer-readable media known to those skilled in the art.

Embodiments of the invention are real-time frameworks that identify the criticality of impacted network elements either when a network outage occurs or when provisioning circuits. The correlation in fiber proximity and diversity checks is to determine the severity of the critical chokepoints of the service impacted collapsed rings. The method employs a network fault management system that monitors and collects network device and traffic conditions in conjunction with network component severity.

Network fault management is the set of functions that detect, isolate, and correct malfunctions in a telecommunications network and include maintaining and examining error logs, accepting and acting on error detection notifications, tracing and identifying faults, carrying out sequences of diagnostics tests, setting thresholds for alarm correlation, correcting faults, reporting error conditions, and localizing and tracing faults by examining and manipulating database information.

When a ring collapse occurs, a network component will send a notification to a network operator using, for example, Simple Network Management Protocol (SNMP). A current list of problems occurring on the network component is typically kept in the form of an active alarm list in an alarm Management Information Base (MIB).

A local network cable inventory contains a tabulation of optical fibers, CLLI, conduits, access points, and enclosures for a predefined market topology. Embodiments import physical elements based on the transport ring identifier from the network fault management system.

The ring identifier can be a numeric number or any characters that are used to specify network transport rings. The market zone is the geographic area of the local network service. It can be represented as a CLLI code or a numeric number. CLLI codes are used to specify the location and type of telecommunications equipment. CLLI codes are associated with vertical and horizontal network coordinates to provide a simple method of calculating distance between two network locations. The most common CLLI code is composed of four sub-fields: four characters for the city, two characters for the state or province, two characters for the specific location or building address, and three characters to specify equipment.

Embodiments display the severity level of common network cable elements and their prioritization directly on a computer (not shown) or via trouble tickets generated for a work center. This reduces the Mean Time To Repair (MTTR), eliminates time-consuming manual intervention to identify chokepoints, and enable the network field operation or support staff to focus on the most critical fibers that requires correction.

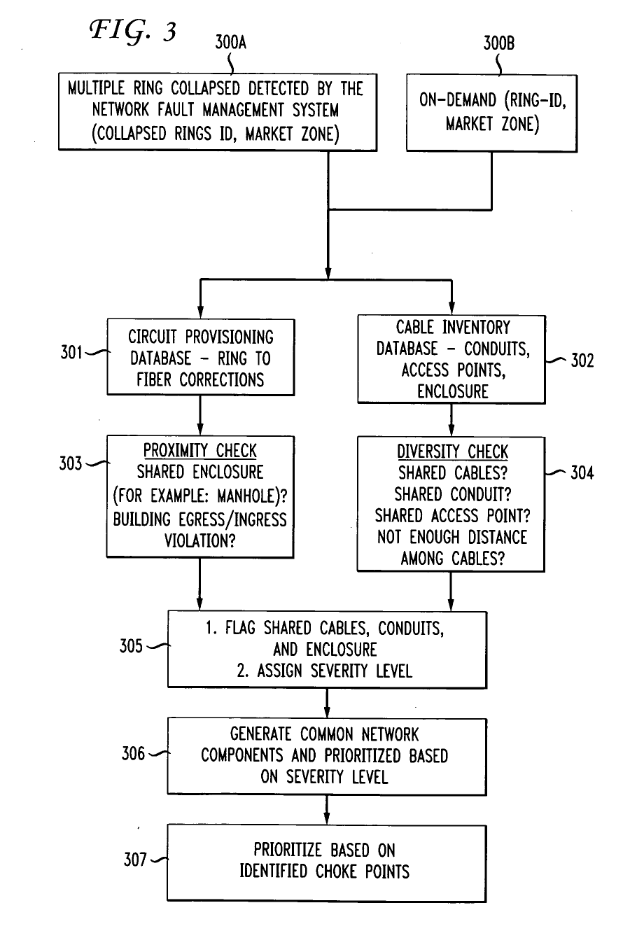

FIG. 3 shows the method. The method monitors the output of a fault management system which determines that a service impacted outage has occurred that has resulted in a massive ring collapse within a predetermined network market zone (step 300A). In an alternative embodiment, a predetermined number of rings with their identifiers and geographical network market zone may be manually entered to identify network chokepoints when network engineering performs circuit provisioning (step 300B).

The network market zone and ring identification, which may be numeric identifications, are automatically imported from the network fault management system or manually inputted as an on-demand request. Based on the ring identification and network market zone, the corresponding optical fiber cable-to-ring correlation data is imported from a circuit provisioning database (step 301). The circuit provisioning database contains detail ring composition and fiber-to-ring correlations identifying the fibers associated with the identified rings. The geographical optical fiber layouts, associated conduits, enclosures, optical fiber termination points, access points, and other physical data are imported from a cable inventory data base (step 302).

Using the identified fibers and associated physical data, a proximity check identifies shared enclosures (step 303). For example, a manhole that is shared by a predetermined number of rings, building ingress/egress violations, and if cables are properly separated. A diversity check is performed on the data to identify shared cables, shared conduits, and shared access points (step 304).

Any shared enclosure(s) among the collapsed rings, or manually input rings within the same geographical network market zone are identified (step 401). Any common cables, conduits and access points (among the collapsed rings, or manually input rings) within the same geographical network market zone are identified (step 305).

Common network elements such as cables, conduits, enclosures, access points are flagged. A severity level for each common network element is calculated, which is the percentage of the number of common elements assigned. For example, a cable that is shared by ten rings out of a total of twelve rings that have collapsed will have a severity level of 83%. Chokepoints are identified as network elements having a predetermined (high) shared level percentage or severity.

Prioritization may be performed based on sorted chokepoint severity level (step 306). The result of the auto-prioritized chokepoint list may be displayed in various ways for the network operation support staff usage. The report of the prioritized chokepoint list can be displayed directly on a computer console that is used by the network operation support center, stored in a file, a link to the file such as a URL or path, can be shown directly on a network dispatch or trouble ticket. The prioritized chokepoint list can also facilitate auditing for mission critical facilities (step 307).

One or more embodiments of the present invention have been described. Nevertheless, it will be understood that various modifications may be made without departing from the spirit and scope of the invention. Accordingly, other embodiments are within the scope of the following claims.

What is claimed is:

1. A method for prioritizing the order of repair of network element damage after a network outage caused by a high number of collapsed rings comprising:
receiving identifiers for the collapsed rings and their geographical market zone from a network fault management system;
importing ring-to-fiber correlation data from a circuit provisioning database based on the collapsed ring and geographical market zone identifiers;
importing geographical cable layouts, associated conduits, enclosures, optical fiber termination points, access points, and other physical data from a cable inventory database based on the collapsed ring and geographical market zone identifiers;
performing a proximity check on the correlation data;
performing a diversity check on the correlation data;
flagging shared network elements identified by the proximity and diversity checks;
calculating a severity for each shared network element; and
prioritizing the shared network elements' severities.

2. The method according to claim 1 wherein the shared network elements are enclosures, fibers, conduits, and access points.

3. The method according to claim 1 wherein the proximity check further comprises identifying cables that share the same enclosure and ingress/egress violations within the same geographical market zone.

4. The method according to claim 1 wherein the diversity check further comprises identifying common network elements such as cables, conduits, and access points among the collapsed rings within the same geographical market zone.

5. The method according to claim 1 wherein the severity of the shared network elements is a percentage of the common network elements (conduit, fiber, access point, and enclosure) associated with the collapsed rings compared to a total number of network elements at that location.

6. The method according to claim 1 wherein the severity of a shared network element determines if it is a chokepoint.

7. The method according to claim 1 further comprising displaying a prioritized shared network elements list on a computer console.

8. The method according to claim 1 further comprising generating an on-demand report.

9. The method according to claim 1 further comprising generating a link to a stored file and showing the link on a network trouble ticket.

10. A method for prioritizing the criticality of network elements in rings when provisioning circuits comprising:
receiving identifiers for the rings and their geographic market zone;
importing ring-to-fiber correlation data from a circuit provisioning database based on the ring and geographical market zone identifiers;
importing geographical cable layouts, associated conduits, enclosures, optical fiber termination points, access points, and other physical data from a cable inventory data base based on the ring and geographical market zone identifiers;
performing a proximity check on the correlation data;
performing a diversity check on the correlation data;
flagging shared network elements identified by the proximity and diversity checks;
calculating a severity for each shared network element; and
prioritizing the shared network elements' severities.

11. The method according to claim 10 wherein the shared network elements are enclosures, fibers, conduits, and access points.

12. The method according to claim 10 wherein the proximity check further comprises identifying cables that share the same enclosure and ingress/egress violations within the same geographical market zone.

13. The method according to claim 10 wherein the diversity check further comprises identifying common network elements such as cables, conduits, and access points among the rings within the same geographical market zone.

14. The method according to claim 10 wherein the severity of the shared network elements is a percentage of the common network elements (conduit, fiber, access point, and enclosure) associated with the rings compared to a total number of network elements at that location.

15. The method according to claim 10 wherein the severity of a shared network element determines if it is a chokepoint.

16. The method according to claim 10 further comprising displaying a prioritized shared network elements list on a computer console.

17. The method according to claim 10 further comprising generating an on-demand report.

18. The method according to claim 10 further comprising generating a link to a stored file, and showing the link on a network trouble ticket.
